(19) United States
(12) Patent Application Publication
(10) Pub. No.: US 2013/0256863 A1
(43) Pub. Date: Oct. 3, 2013

(54) EPOXY RESIN COMPOSITION FOR SEMICONDUCTOR ENCAPSULATION AND SEMICONDUCTOR DEVICE

(71) Applicant: Shingo Ito, Tokyo (JP)

(72) Inventor: Shingo Ito, Tokyo (JP)

(73) Assignee: SUMITOMO BAKELITE CO., LTD., Tokyo (JP)

(21) Appl. No.: 13/988,534

(22) PCT Filed: Nov. 21, 2011
(86) PCT No.: PCT/JP2011/076799

§ 371 Date: May 21, 2013

(30) Foreign Application Priority Data
Nov. 24, 2010 (JP) 2010-260913

(51) Int. Cl. H01L 23/29

(52) U.S. Cl. CPC H01L 23/295
USPC 257/676; 523/400

(57) ABSTRACT

A highly reliable semiconductor device with the improved humidity resistance reliability is disclosed. A disclosed epoxy resin composition for semiconductor encapsulation encapsulates, in the manufacture of the semiconductor device, a semiconductor element that is mounted on a lead frame having a die pad unit or a circuit substrate and a wire that connects an electrical junction disposed on the lead frame or circuit substrate and an electrode pad disposed on the semiconductor element. The epoxy resin composition includes an epoxy resin (A), a curing agent (B), and an inorganic filler (C). The epoxy resin (A) has a main peak area of 90% or more with respect to the total area of all peaks as measured by the gel permeation chromatography area method.

### TECHNICAL FIELD OF THE INVENTION

The present invention relates to an epoxy resin composition for semiconductor encapsulation and a semiconductor device that is encapsulated with the aforementioned epoxy resin composition for encapsulation.

Priority is claimed on Japanese Patent Application No. 2010-260913, filed on Nov. 24, 2010, the content of which is incorporated by reference herein.

### PRIOR ART

Electronic components such as diodes, transistors, and integrating circuits have thus far been mainly encapsulated with a cured epoxy resin composition. In particular, regarding integrating circuits, an epoxy resin composition which is a mixture of an epoxy resin, a curing agent that is based on a phenol resin, and an inorganic filler such as fused silica and crystalline silica and exhibits excellent performance in terms of heat resistance and moisture resistance has been used. However, with the recent market trend towards miniaturization, lighter design, and high performance of electronic instruments, with a year-by-year advancement of semiconductor device integration and progress in surface mount technology of semiconductor devices, tough demands have been placed on epoxy resin compositions used for semiconductor device encapsulation.

On the other hand, another tough demand has also been placed on cost reduction of semiconductor devices. In recent years, a copper wire has been proposed, which is expected as a cheap bonding wire in place of a gold wire.

Patent Document 1 describes a bonding wire. The bonding wire is composed of a core material that includes copper as a main ingredient and a skin layer that is provided over the core material and includes copper and conductive metals, wherein either or both of the components and compositions of the skin layer are different from those of the core material. The bonding wire having a skin layer thickness of from 0.001 μm to 0.02 μm is described to provide a copper-based bonding wire that is cheap in material cost, having excellent ball-bonding and wire-bonding performance and an adequate loop-forming performance. The copper-based bonding wire may be applicable not only to fine wiring with narrow pitches but also to thick wiring for power ICs.

However, when a semiconductor element that is bonded with the aforementioned copper wire is encapsulated with a conventional epoxy resin composition, humidity resistance reliability (HAST: Highly Accelerated Temperature & Humidity Test) of the resulting semiconductor device has been sometimes lowered.

In a semiconductor device with low humidity resistance reliability, the present inventors have found that corrosion at the junction between an electrode pad and the copper wire on a semiconductor element causes elevation of electrical resistance or wire disconnection at the junction. Therefore, when such elevation of electrical resistance or wire disconnection at the junction is prevented, the humidity resistance reliability of semiconductor devices is expected to be improved.

### CITATION LIST

### Patent Document

Patent Document 1: Japanese Unexamined Patent Application, First Publication No. 2007-12776

### SUMMARY OF INVENTION

### Problems to be Solved by the Invention

In view of the above circumstances, the present invention has been achieved. An object of the present invention is to provide an epoxy resin composition for semiconductor encapsulation and a semiconductor device that is encapsulated with a cured article of the epoxy resin composition for semiconductor encapsulation. The epoxy resin composition lowers corrosion at a junction between an electrode pad and a metal wire on a semiconductor element under high-temperature and high-humidity conditions and provides the semiconductor device with improved reliability.

### Means for Solving the Problem

[1] The present invention provides an epoxy resin composition for semiconductor encapsulation, which is used to produce a semiconductor device by encapsulating a semiconductor element that is mounted on a lead frame having a die pad unit or a circuit substrate, and a metal wire that electrically connects an electrode pad disposed on the semiconductor element and an electrical junction disposed on the lead frame or the circuit substrate; the epoxy resin composition for semiconductor encapsulation includes therein an epoxy resin (A), a curing agent (B), and an inorganic filler (C), in which the epoxy resin (A) has a main peak area of 90% or more with respect to the total area of all peaks as measured by a gel permeation chromatography area method.

[2] The present invention provides an epoxy resin composition for semiconductor encapsulation as described in [1], wherein the epoxy resin (A) has a main peak area of 92% or more with respect to the total area of all peaks as measured by the gel permeation chromatography area method.

[3] The present invention provides an epoxy resin composition for semiconductor encapsulation as described in any one of [1] and [2], wherein the epoxy resin (A) has a total chlorine content of 300 ppm or less and a hydrolysable chlorine content of 150 ppm or less.

[4] The present invention provides an epoxy resin composition for semiconductor encapsulation as described in any one of [1] and [2], wherein the epoxy resin (A) has a total chlorine content of 200 ppm or less and a hydrolysable chlorine content of 100 ppm or less.

[5] The present invention provides an epoxy resin composition for semiconductor encapsulation as described in any one of [1] to [4], wherein the epoxy resin (A) includes an epoxy resin that is represented by the following formula (1),

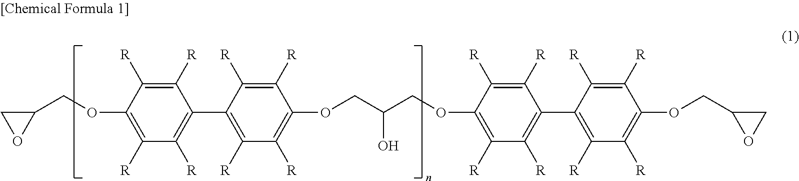

In the above formula (1), each R represents, independently from one another, a hydrogen atom or a hydrocarbon group having 1 to 4 carbon atoms; n represents polymerization degree; and the average value of n is a positive number from 0 to 4.

[6] The present invention provides an epoxy resin composition for semiconductor encapsulation as described in any one of [1] to [5], wherein a blending ratio of the epoxy resin (A) is from 3% by mass to 20% by mass with respect to the total amount of the epoxy resin composition for semiconductor encapsulation.

[7] The present invention provides an epoxy resin composition for semiconductor encapsulation as described in any one of [1] to [6], wherein the metal wire is a copper wire.

[8] The present invention provides an epoxy resin composition for semiconductor encapsulation as described in [7], wherein a dopant in an amount of 0.1% by mass or less with respect to copper of the copper wire is added; and the copper purity of the copper wire is 99.9% by mass or more.

[9] The present invention provides a semiconductor device, including a semiconductor element mounted on a lead frame having a die pad unit or on a circuit substrate, and a metal wire electrically connecting an electrical junction disposed on the lead frame or the circuit substrate and an electrode pad disposed on the semiconductor element, and the semiconductor element and the metal wire being encapsulated with a cured article of the epoxy resin composition for semiconductor encapsulation as described in any one of [1] to [8].

The present invention provides a semiconductor device as described in [9], wherein the metal wire is a copper wire.

### Effects of the Invention

An epoxy resin composition for semiconductor encapsulation according to the present invention provides a highly reliable semiconductor device that has an improved humidity resistance reliability.

### BRIEF DESCRIPTION OF THE DRAWINGS

FIG. 1 is a schematic diagram representing the cross-section of a semiconductor device of the present invention.

### EMBODIMENTS OF THE INVENTION

Hereinafter, embodiments of the present invention are described with reference to figures. Note that, in all of the figures, the same constituents are indicated by the same reference numbers, and repeated explanations thereof are abbreviated appropriately.

An epoxy resin composition for semiconductor encapsulation according to the present invention is used to produce a semiconductor device, wherein a semiconductor element mounted on a lead frame having a die pad unit or a circuit substrate and a metal wire that electrically connects an electrical junction disposed on the lead frame or circuit substrate and an electrode pad disposed on the semiconductor element are encapsulated therewith. The epoxy resin composition for semiconductor encapsulation includes therein an epoxy resin (A), a curing agent (B), and an inorganic filler (C). The epoxy resin (A) has a main peak area of 90% or more with respect to the total area of all peaks as measured by the gel permeation chromatography area method.

The epoxy resin composition for semiconductor encapsulation according to the present invention includes therein the epoxy resin (A).

The epoxy resin (A) includes monomers, oligomers, and polymers that have two or more epoxy groups per molecule. The molecular weight and molecular structure thereof are not limitative. Examples of the epoxy resin (A) include bisphenol epoxy resins and stilbene epoxy resins such as biphenyl epoxy resins, bisphenol A epoxy resins, bisphenol F epoxy resins, and tetramethyl bisphenol F epoxy resins; novolak epoxy resins such as phenol novolak epoxy resins and cresol novolak epoxy resins; polyfunctional epoxy resins such as triphenolmethane epoxy resins and alkyl-modified triphenolmethane epoxy resins; aralkyl epoxy resins such as phenolaralkyl epoxy resins having a phenylene structure, naphtholaralkyl epoxy resins having a phenylene structure, and phenolaralkyl epoxy resins having a biphenylene structure; dihydroanthracenediol epoxy resins; naphthoyl epoxy resins such as an epoxy resin that is obtained by glycidyl etherifying a dihydroxynaphthalene dimer; epoxy resins having a triazine nucleus such as triglycidyl isocyanurate and monoallyl diglycidyl isocyanurate; and phenol epoxy resins modified with bridged cyclic hydrocarbon compounds such as phenol epoxy resin modified with dicyclopentadiene. These may be used as one kind solely or two or more kinds in combination.

Among these, epoxy resins that exhibit high crystallinity after an appropriate synthetic or purification method is performed are more preferable. Examples of these epoxy resins include biphenyl epoxy resins, bisphenol A epoxy resins, bisphenol F epoxy resins, tetramethyl bisphenol F epoxy resins, and stilbene epoxy resins.

The epoxy resin (A) that is used in the present invention has a main peak area of 90% or more with respect to the total area of all peaks as measured by the gel permeation chromatography area method. More preferably, the main peak area is 92% or more with respect to the total area of all peaks. Particularly preferably, the main peak area is 95% or more with respect to the total area of all peaks.

Note that, the main peak of the epoxy resin (A) as measured by the gel permeation chromatography area method denotes a peak that has the largest area among gel permeation chromatography peaks. The main peak may be used as an index of epoxy resin purity.

The epoxy resin (A) that has a main peak area within the aforementioned range with respect to the total area of all peaks contains less chlorine-containing byproducts, providing an epoxy resin composition that contains less corrosive impurities.

Examples of a general method of synthesizing epoxy resins may include a method where phenol resins that are precursors of the epoxy resins are dissolved in excess epihalohydrins such as epichlorohydrin, and then, they are reacted in the presence of an alkali metal hydroxide such as sodium hydroxide and potassium hydroxide at 50-150° C. and preferably 60-120° C. for 1-10 h.

After reaction, excess epichlorohydrin is removed by distillation; residues are dissolved in a solvent such as toluene and methylisobutylketone, filtered off, and water-washed so as to remove inorganic salts; then, the solvent is removed by distillation so as to obtain an epoxy resin.

In particular, examples of a method of preparing the epoxy resin (A) that is used in the present invention include a method of reducing the blending amount of epihalohydrin within a range where high polymerization caused by self-polymerization does not occur upon synthesis and a method of reducing the blending amount or concentration of the alkali metal hydroxide within a range where halogen adducts or non-closed ring epoxy groups are not in excess.

In addition, a specific resin that is defined by the present invention may be prepared from an epoxy resin that is synthesized by known methods or a commercially available epoxy resin, wherein known purification methods including column chromatography separation, molecular distillation, and recrystallization are used in combination appropriately.

Alternatively, a commercially available epoxy resin that is prepared as described above may be used. Examples of the commercially available one may include “YX4000UH” (trade name: manufactured by Mitsubishi Chemical Corp.) and “YL7684” (trade name: manufactured by Mitsubishi Chemical Corp.).

In the present invention, the gel permeation chromatography (GPC) measurement for the epoxy resin (A) is performed as follows.

A GPC instrument is composed of a pump, an injector, a guard column, a column, and a detector. Tetrahydrofuran is used as solvent. In the measurement, the flow-rate of the pump is selected to be 0.5 mL/min. A flow-rate higher than 0.5 mL/min is not appropriate because detection accuracy of an object molecular weight is lowered. In order to perform the measurement with good accuracy at the aforementioned flow rate, it is necessary to use a pump that has a flow rate with good accuracy. The flow-rate accuracy is preferably 0.10% or less. For the guard column, commercially available guard columns (for instance, “TSK GUARDCOLUMN HHR-L” (trade name, manufactured by Tosoh Corp., 6.0 mm in diameter, 40 mm in length) are used. For the column, commercially available polystyrene gel columns (“TSK-GEL GMHHR-L” (trade name, manufactured by Tosoh Corp., 7.8 mm in diameter, 30 mm in length) are used. Two or more of these columns are connected to each other in series. For the detector, a refractive index detector (RI detector, for instance, “RI DETECTOR W2414” (trade name, manufactured by WATERS Corp.) is used. Prior to the measurement, the insides of the guard column, column, and detector are stabilized at 40° C. As a test sample, a THF solution that dissolves the epoxy resin (A) in a concentration of 3 mg/mL to 4 mg/mL is prepared. The solution is injected in an amount of about 50-150 μL through an injector, so that the measurement is performed.

Furthermore, the epoxy resin (A) that is used in the present invention preferably has a total chlorine content of 300 ppm or less and a hydrolysable chlorine content of 150 ppm or less.

More preferably, the total chlorine content is 200 ppm or less and the hydrolysable chlorine content is 100 ppm or less.

Particularly preferably, the total chlorine content is 50 ppm or less and the hydrolysable chlorine content is 30 ppm or less.

By using the aforementioned epoxy resin (A), a semiconductor device that has a high humidity resistance reliability is attainable.

Chloride ions are corrosive to metal and corrode aluminum wiring such as an electrode pad that is disposed on a semiconductor element. When a copper wire is used as a metal wire for an electrical junction of a semiconductor element, an alloy of aluminum and copper is formed at the junction. The alloy behaves as a galvanic pair, so that the alloy particularly easily suffers from chlorine corrosion. Ultimately, the alloy lowers the humidity resistance reliability. In order to improve the humidity resistance reliability of a semiconductor device, it is necessary to reduce the chlorine content in the epoxy resin composition for semiconductor encapsulation.

Chlorine that is contained in an epoxy resin composition for semiconductor encapsulation is derived from an epoxy resin. The epoxy resin is synthesized from epichlorohydrin that contains chlorine, so that even a high-purity epoxy resin that is used as an electronic material has a total chlorine content of 600 ppm or more. At least 50% of chlorine that is contained in epoxy is hydrolysable and is easily freed in the form of chloride ions. When the total chlorine content and hydrolysable chlorine content are within the aforementioned ranges, the humidity resistance reliability of a semiconductor device is greatly improved.

A high molecular weight moiety of an epoxy resin contains much chlorine; on the other hand, the main peak area that is a lowest molecular weight moiety (corresponding to the case where n is 0 (zero) in the following formula (1)) contains less chlorine. Namely, the main peak area is on the side of low molecular weight, so that an epoxy resin on the side of lower molecular weight contains less chlorine. An epoxy resin of which the main peak area is in the aforementioned range with respect to the total area of all peaks as measured by the gel permeation chromatography area method limits the total chlorine content and hydrolysable chlorine content within the aforementioned ranges. Such an epoxy resin provides a resin composition for semiconductor encapsulation that has an extremely low content of chlorine.

The total chlorine content of an epoxy resin is measured in accordance with JIS K7229 (quantitative analysis of chlorine that is contained in chlorine-containing resins). The hydrolysable chlorine content is measured in accordance with JIS K6755 (quantitative analysis of saponifiable chlorine that is contained in epoxy resins).

The epoxy resin (A) that is usable in the present invention includes an epoxy resin that is represented by the following formula (1).

The epoxy resin that is represented by the formula (1) is a crystalline epoxy resin, so that, through recrystallization purification, an epoxy resin that has a main peak area of 90% or more with respect to the total area of all peaks as measured by the gel permeation chromatography area method is relatively easily obtained.

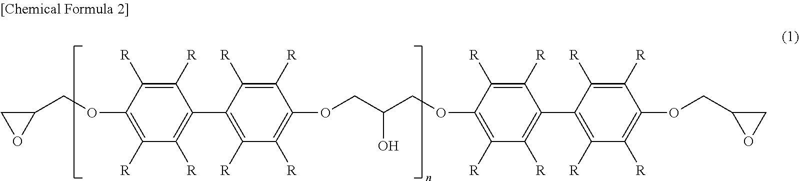

In the above formula (1), each R represents, independently from one another, a hydrogen atom or a hydrocarbon group having 1 to 4 carbon atoms; n represents polymerization degree; and the average value of n is a positive number from 0 to 4.

In particular, in order to use the epoxy resin represented by the formula (1) for semiconductor encapsulation, n is preferably 0 (zero) to 3, more preferably 0 (zero) to 2, and most preferably 0 (zero).

The blending ratio of the epoxy resin (A) is not particularly limited, but preferably from 3% by mass to 20% by mass with respect to the total amount of the epoxy resin composition for semiconductor encapsulation, and more preferably from 5% by mass to 18% by mass. The lower limit of the blending ratio of the epoxy resin (A) is not particularly limited, but preferably 3% by mass or more with respect to the total amount of the epoxy resin composition for semiconductor encapsulation, and more preferably 5% by mass or more. The reason thereof comes from the fact that when the lower limit of the blending ratio of the epoxy resin (A) is within the aforementioned range, a low frequency of wire-cutting fault that is caused by viscosity increase is assured. The upper limit of the blending ratio of the epoxy resin (A) is not particularly limited, but preferably 20% by mass or less with respect to the total amount of the epoxy resin composition for semiconductor encapsulation and more preferably 18% by mass or less. The reason thereof comes from the fact that when the upper limit of the blending ratio of the epoxy resin (A) is within the aforementioned range, a low frequency of degradation in the humidity resistance reliability that is caused by water absorption increase is assured.

The curing agent (B) that is used for the epoxy resin composition for semiconductor encapsulation according to the present invention may be roughly classified into three types: a polyaddition curing agent; a catalytic curing agent; and a condensation curing agent, for example.

Examples of the polyaddition curing agent include polyamine compounds that include aliphatic polyamines such as diethylene triamine (DETA), triethylene tetramine (TETA) and methaxylylene diamine (MXDA), aromatic polyamines such as diaminodiphenyl methane (DDM), m-phenylene diamine (MPDA) and diaminodiphenyl sulfone (DDS), dicyanediamide (DICY), and organic acid dihydrazide; acid anhydrides that include alicyclic acid anhydrides such as hexahydrophthalic anhydride (HHPA) and methyltetrahydrophthalic anhydride (MTHPA) and aromatic acid anhydrides such as trimellitic anhydride (TMA), pyromellitic anhydride (PMDA) and benzophenone tetracarboxylic acid (BTDA); polyphenol compounds that include phenols such as phenol resins, phenol resins that are synthesized through condensation between phenols such as phenol and naphthol and ketones or aldehydes, and phenol polymers that are typified by polyvinylphenol; polymercaptan compounds such as polysulfides, thioesters, and thioethers; isocyanate compounds such as isocyanate prepolymers and blocked isocyanates; and organic acids such as carboxylic acid-containing polyester resins.

Examples of the catalytic curing agent include tertiary amine compounds such as benzyl dimethyl amine (BDMA) and 2,4,6-trisdimethyl aminomethyl phenol (DMP-30); imidazole compounds such as 2-methyl imidazole and 2-ethyl-4-methyl imidazole (EMI24); and Lewis acids such as BF3 complexes.

Examples of the condensation-curing agent include phenol resin curing agents such as resol phenol resins; urea resins such as methylol group-containing urea resins; and melamine resins such as methylol group-containing melamine resins.

Among these, the phenol resin curing agents are preferable considering flame resistance, moisture resistance, electrical properties, curing performance, storage stability, and other factors.

The phenol resin curing agents include all of the monomers, oligomers, and polymers that have two or more phenolic hydroxyl groups per molecule. Molecular weight and molecular structure thereof are not particularly limited. Examples of the phenol resin curing agents include novolak resins such as phenolnovolak resins, cresolnovolak resins, and bisphenolnovolak; polyfunctional phenol resins such as triphenolmethane phenol resins; modified phenol resins such as terpene-modified phenol resins and dicyclopentadiene-modified phenol resins; aralkyl resins such as phenolaralkyl resins that have phenylene and/or biphenylene structures and naphtholaralkyl resins that have phenylene and/or biphenylene structures; and bisphenol compounds such as bisphenol A and bisphenol F. These may be used as one kind solely or two or more kinds in combination.

The blending ratio of the curing agent (B) is not particularly limited, but preferably from 0.8% by mass to 16% by mass with respect to the total amount of the epoxy resin composition for semiconductor encapsulation and more preferably from 1.5% by mass to 14% by mass. The lower limit of the blending ratio of the curing agent (B) is not particularly limited, but preferably 0.8% by mass or more with respect to the total amount of the epoxy resin composition for semiconductor encapsulation and more preferably 1.5% by mass or more. The reason thereof comes from the fact that when the lower limit of the blending ratio is within the aforementioned range, sufficient fluidity is obtainable.

In addition, the upper limit of the blending ratio of the curing agent (B) is not particularly limited, but preferably 16% by mass or less with respect to the total amount of the epoxy resin composition for semiconductor encapsulation and more preferably 14% by mass or less. The reason thereof comes from the fact that when the upper limit of the blending ratio is within the aforementioned range, a low frequency of degradation in the humidity resistance reliability that is caused by water absorption increase is assured.

In the case of using a phenol resin curing agent as the curing agent (B), the blending ratio of the epoxy resin to the phenol resin curing agent is preferably from 0.8 to 1.3 in terms of the equivalence ratio of (EP)/(OH), wherein (EP) is the number of epoxy groups contained in the whole epoxy resin and (OH) is the number of phenolic hydroxyl groups contained in the whole phenol resin curing agent. When the equivalence ratio is within the aforementioned range, a low frequency of degradation in the curing performance of the epoxy resin composition for semiconductor encapsulation or a low frequency of degradation in the performance of cured resin articles is assured.

As the inorganic filler (C) that is used in the epoxy resin composition for semiconductor encapsulation according to the present invention, an inorganic filler that is used in conventional epoxy resin compositions for semiconductor encapsulation is usable. Examples thereof include fused spherical silica; pulverized fused silica; crystalline silica; talc; alumina; titanium white; and silicon nitride. Among these, fused spherical silica is particularly preferable. These inorganic fillers may be used as one kind solely or two or more kinds in combination. The shape of the inorganic filler (C) is preferably as close to spherical as possible and the particle size distribution thereof is preferably broad, whereby an increase in the melt viscosity of the epoxy resin composition for semiconductor encapsulation is suppressed and the content of the inorganic filler is increased. The inorganic filler (C) may be subjected to surface treatment with a coupling agent. As required, the inorganic filler (C) may be subjected to a preliminary treatment with an epoxy resin or a phenol resin. Examples of the treatment include a method of mixing in a solvent and then removing it; and a method of directly adding to the inorganic filler (C) and then mixing with a blending machine.

The content ratio of the inorganic filler (C) is not particularly limited, but preferably from 60% by mass to 92% by mass with respect to the total amount of the epoxy resin composition for semiconductor encapsulation, and more preferably from 65% by mass to 89% by mass. The lower limit of the content ratio of the inorganic filler (C) is not particularly limited, but preferably 60% by mass or more with respect to the total amount of the epoxy resin composition for semiconductor encapsulation, considering the filling performance of the epoxy resin composition for semiconductor encapsulation and the reliability of semiconductor devices, and more preferably 65% by mass or more. The reason thereof comes from the fact that a low humidity absorption and a low thermal expansion are attained and that a low frequency of insufficient humidity resistance reliability is assured. The upper limit of the content ratio of the inorganic filler is, considering moldability, preferably 92% by mass or less with respect to the total amount of the epoxy resin composition for semiconductor encapsulation, and more preferably 89% by mass or less. The reason thereof comes from the fact that when the upper limit is within the aforementioned range, a low frequency of degradation in fluidity, filling fault upon molding, and inconvenience such as wire flow in semiconductor devices that is caused by viscosity increase is assured.

The epoxy resin composition for semiconductor encapsulation according to the present invention may further include therein a curing promoter.

Specific examples of the curing promoter include phosphorus-containing compounds such as organic phosphines, tetra-substituted phosphonium compounds, phosphobetaine compounds, adducts between phosphine compounds and quinone compounds, and adducts between phosphonium compounds and silane compounds; and nitrogen-containing compounds that include amidines or tertiary amines such as 1,8-diazabicyclo(5,4,0) undecene-7, benzyl dimethylamine, and 2-methylimidazole; and the quaternary salts of the aforementioned amidines or amines. These may be used as one kind solely or two or more kinds in combination. Among these, the phosphorus-containing compounds are preferable, considering curing performance. Considering solder resistance and fluidity, the phosphobetaine compounds and adducts between phosphine compounds and quinone compounds are particularly preferable. Considering less staining performance to a mold upon continuous molding, the phosphorus-containing compounds such as the tetra-substituted phosphonium compounds and adducts between phosphonium compounds and silane compounds are particularly preferable.

Examples of the organic phosphines usable in the resin composition include primary phosphines such as ethylphosphine and phenylphosphine; secondary phosphines such as dimethylphosphine and diphenylphosphine; and tertiary phosphines such as trimethylphosphine, triethylphosphine, tributylphosphine, and triphenylphosphine.

Examples of the tetra-substituted phosphonium compounds usable in the resin composition include compounds that are represented by the following formula (2).

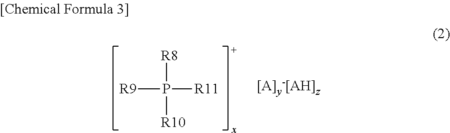

In the above formula (2), P represents a phosphorous atom. Each of R8, R9, R10, and R11 represents an aromatic group or an alkyl group. A represents an anion of aromatic organic acids that have in their aromatic rings at least one functional group selected from the group consisting of a hydroxyl group, a carboxyl group, and a thiol group. AH represents an aromatic organic acid that has in the aromatic ring thereof at least one functional group selected from the group of a hydroxyl group, a carboxyl group, and a thiol group. x and y represent integers of from 1 to 3; z represents an integer of from 0 (zero) to 3; and x is equal to y.

The compound represented by the formula (2) is obtained as follows, but is not limited to the following. At first, tetra-substituted phosphonium halide and an aromatic organic acid, and a base are blended with an organic solvent, and they are mixed uniformly so as to generate aromatic organic acid anions in the resulting solution; then, water is added, so that the compound that is represented by the formula (2) is precipitated. In the compound that is represented by the formula (2), preferably, each of R7, R8, R9, and R 10 that bind to phosphorous atom is a phenyl group; AH is a compound that has a hydroxyl group in the aromatic ring thereof; namely, it represents phenols; and A is an anion of the aforementioned phenols. Examples of the phenols in the present invention include monocyclic phenols such as phenol, cresol, resorsin, and catechol; condensed polycyclic phenols such as naphthol, dihydroxynaphthalene, and anthraquinol; bisphenols such as bisphenol A, bisphenol F, and bisphenol S; and polycyclic phenols such as phenylphenol and biphenol.

Examples of the phosphobetaine compounds include the compounds that are represented by the following formula (3).

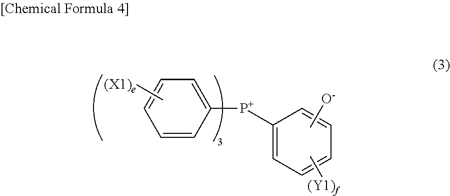

In the above formula (3), X1 represents an alkyl group having 1 to 3 carbon atoms; Y1 represents a hydroxyl group; e represents an integer of 0 (zero) to 5; and f represents an integer of 0 (zero) to 3.

The compounds that are represented by the formula (3) are obtained as follows, for example. They are obtained through a process in which a tri-aromatic substituted phosphine that is a tertiary phosphine is contacted with a diazonium salt, whereby the diazonium group of the diazonium salt is replaced by the tri-aromatic substituted phosphine. However, the process is not limited to the above.

Examples of the adducts between phosphine compounds and quinone compounds include the compounds that are represented by the following formula (4).

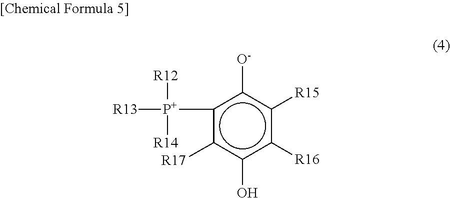

In the above formula (4), P represents a phosphorus atom. Each of R12, R13, and R14 represents an alkyl group having 1 to 12 carbon atoms or an aryl group having 6 to 12 carbon atoms, and each may be the same or different from one another. Each of R15, R16, and R17 represents a hydrogen atom or a hydrocarbon group having 1 to 12 carbon atoms, each may be the same or different from one another, and R15 and R16 may bind together to form a ring structure.

Examples of phosphine compounds that are used for the adducts between phosphine compounds and quinone compounds include preferably the ones that have or do not have a substitution group such as an alkyl group or an alkoxyl group in the aromatic ring of triphenylphosphine, tris(alkylphenyl) phosphine, tris(alkoxyphenyl) phosphine, trinaphthylphosphine, tris(benzyl) phosphine, and the like. Examples of the substitution group such as an alkyl group and an alkoxyl group include one that has 1 to 6 carbon atoms. Considering availability, triphenylphosphine is preferable.

The quinone compounds that are used for the adducts between phosphine compounds and quinone compounds include o-benzoquinone, p-benzoquinone, and anthraquinone. Among these, p-benzoquinone is preferable considering storage stability.

In a method of producing the adducts between phosphine compounds and quinone compounds, the adducts are obtained by contacting and mixing organic tertiary phosphine and benzoquinone in a solvent in which both of them are dissolvable. The solvent is preferably ketones such as acetone and methylethylketone that has low solubility to the adducts. However, the method is not limited to the above.

Among the compounds that are represented by the formula (4), a compound in which each of R11, R12, and R13 that bind to the phosphorus atom is a phenyl group and each of R14, R15, and R16 is a hydrogen atom, that is, a compound that is an adduct between 1,4-benzoquinone and triphenylphosphine is preferable, considering that a cured article of the resin composition reduces the elasticity thereof on heating.

Examples of the adducts between phosphonium compounds and silane compounds include the compounds that are represented by the following formula (5).

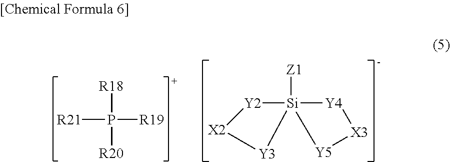

In the above formula (5), P represents a phosphorus atom and Si represents a silicon atom. Each of R18, R19, R20, and R21 represents an organic group that has an aromatic ring or a heterocyclic ring, or an aliphatic group; and each may be the same or different from one another. In the formula, X2 represents an organic group that binds to a group of Y2 and a group of Y3. In the formula, X3 represents an organic group that binds to a group of Y4 and a group of Y5. Each of Y2 and Y3 represents a group that remains after a proton-donating group loses a proton. The groups of Y2 and Y3 that exist in the same molecule bind to the silicon atom to form a chelate structure. Each of Y4 and Y5 represents a group that remains after a proton-donating group loses a proton. The groups of Y4 and Y5 that exist in the same molecule bind to the silicon atom to form a chelate structure. Each of X2 and X3 may be the same or different from each other. Each of Y2, Y3, Y4, and Y5 may be the same or different from one another. Z1 represents an organic group that has an aromatic ring or a heterocyclic ring, or an aliphatic group.

In the formula (5), examples of R18, R19, R20, and R21 include a phenyl group, a methylphenyl group, a methoxyphenyl group, a hydroxyphenyl group, a naphthyl group, a hydroxynaphthyl group, a benzyl group, a methyl group, an ethyl group, an n-butyl group, an n-octyl group, and a cylohexyl group. Among these, an aromatic group that has a substitution group such as a phenyl group, a methylphenyl group, a methoxyphenyl group, a hydroxyphenyl group and a hydroxynaphthyl group, or a non-substituted aromatic group is preferable.

In the formula (5), X2 represents an organic group that binds to Y2 and Y3. Similarly, X3 represents an organic group that binds to groups of Y4 and Y5. Each of Y2 and Y3 is a group that remains after a proton-donating group loses a proton. The groups of Y2 and Y3 that exist in the same molecule bind to the silicon atom and form a chelate structure. Similarly, each of Y4 and Y5 is a group that remains after a proton-donating group loses a proton. The groups of Y4 and Y5 that exist in the same molecule bind to the silicon atom and form a chelate structure. Each group of X2 and X3 may be the same or different from each other. Each group of Y2, Y3, Y4, and Y5 may be the same or different from one another. In the formula (5), each group that is represented by —Y2-X2-Y3- and —Y4-X3-Y5- respectively consists of a group that remains after a proton donor loses two protons. A preferable proton donor is an organic acid that has at least two carboxyl groups or hydroxyl groups in the molecule. In addition to that, aromatic compounds that have at least two carboxyl groups or hydroxyl groups in all at an adjacent carbon atom of an aromatic ring are preferable. Among these, an aromatic compound that has at least two hydroxyl groups in all at a carbon atom that forms an aromatic ring is preferable. Examples thereof include catechol, pyrogallol, 1,2-dihydroxynaphthalene, 2,3-dihydroxynaphthalene, 2,2′-biphenol, 1,1′-bi-2-naphthol, salicylic acid, 1-hydroxy-2-naphtoic acid, 3-hydroxy-2-naphtoic acid, chloranilic acid, tannic acid, 2-hydroxybenzylalcohol, 1,2-cyclohexanediol, 1,2-propanediol, and glycerin. Among these, catechol, 1,2-dihydroxynaphthalene, and 2,3-dihyroxynaphthalene are preferable.

Z1 in the formula (5) represents an organic group that has an aromatic ring or a heterocyclic ring, or an aliphatic group. Specific examples thereof include an aliphatic hydrocarbon group such as a methyl group, an ethyl group, a propyl group, a butyl group, a hexyl group, and an octyl group; an aromatic hydrocarbon group such as a phenyl group, a benzyl group, a naphthyl group, and a biphenyl group; and a reactive substitution group such as a glycidyloxypropyl group, a mercaptopropyl group, an aminopropyl group, and a vinyl group. Among these, a methyl group, an ethyl group, a phenyl group, and a biphenyl group are preferable, considering thermal stability.

A method of producing the adducts between phosphonium compounds and silane compounds is as follows: in a flask charged with methanol, a silane compound such as phenyltrimethoxysilane and a proton donor such as 2,3-dihydroxynaphthalene are added and dissolved; then, a methanol solution of sodium methoxide is added dropwise at room temperature while stirring. Further, a solution that is preliminarily prepared by dissolving a tetra-substituted phosphonium halide such as tetraphenylphosphonium bromide in methanol is added dropwise to the flask at room temperature while stirring, so that crystals are precipitated; the precipitated crystals are filtered off, water-washed, and vacuum-dried, so that the adducts between phosphonium compounds and silane compounds are obtained. However, the method of producing the adducts is not limited to the above.

By using the compounds represented by the formulas (2) to (5) as the curing promoter, favorably, viscosity increase on melting of the resin composition is suppressed or prevented while the filling amount of the inorganic filler increases.

The blending ratio of the curing promoter is not particularly limited, but preferably from 0.05% by mass to 1% by mass with respect to the total amount of the epoxy resin composition for semiconductor encapsulation, and more preferably from 0.1% by mass to 0.5% by mass. The lower limit of the blending ratio of the curing promoter is not particularly limited, but preferably 0.05% by mass or more with respect to the total amount of the epoxy resin composition for semiconductor encapsulation, and more preferably 0.1% by mass or more. The reason thereof comes from the fact that when the lower limit of the blending ratio of the curing promoter is within the aforementioned range, low frequency of degradation in curing performance is assured. The upper limit of the blending ratio of the curing promoter is not particularly limited, but preferably 1% by mass or less with respect to the total amount of the epoxy resin composition for semiconductor encapsulation, and more preferably 0.5% by mass or less. The reason thereof comes from the fact that when the upper limit of the blending ratio of the curing promoter is within the aforementioned range, low frequency of degradation in fluidity is assured.

The epoxy resin composition for semiconductor encapsulation according to the present invention may be further blended appropriately with various kinds of additives, as required. The additives include corrosion inhibitors such as hydrotalcite and zirconium hydroxide; inorganic ion exchangers such as bismuth oxide hydrates; coupling agents such as γ-glycidoxypropyl trimethoxysilane, 3-mercaptopropyl trimethoxysilane, and 3-aminopropyl trimethoxysilane; colorants such as carbon black and red iron oxide; low-stress components such as silicone rubber; mold-releasing agents such as natural wax including carnauba wax, synthetic wax, higher fatty acids and their metal salts including zinc stearate, and paraffin; and oxidation inhibitors.

The epoxy resin composition for semiconductor encapsulation that is used for semiconductor device of the present invention is prepared, for example, by mixing the aforementioned components with a blending machine or the like at 15° C. to 28° C. Further, after that, they may be melt-kneaded with a kneading machine such as a roller, a kneader, and an extruder, and then pulverized after cooling. Alternatively, as required, dispersivity or fluidity thereof may be regulated appropriately.

A cured article of the epoxy resin composition for semiconductor encapsulation according to the present invention may be obtained by molding and curing the epoxy resin composition, wherein conventional molding processes including transfer molding, compression molding, and injection molding are used. A cured article of the epoxy resin composition that is molded and cured by a molding process such as transfer molding may also be obtained, as required, through full curing at a temperature of 80° C. to 200° C. for about 10 min to 10 h.

Because the total chlorine content and hydrolysable chlorine content of the epoxy resin (A) are low, corrosion is not easily developed at a junction to an electrode pad disposed on a semiconductor element even though a copper wire is used as the metal wire. Whereby, a highly reliable semiconductor device is produced at low cost.

Next, the semiconductor device according of the present invention is described.

In a semiconductor device of the present invention, a semiconductor element that is mounted on a lead frame having a die pad unit or a circuit substrate and a metal wire that electrically connects an electrical junction disposed on the lead frame or circuit substrate and an electrode pad disposed on the semiconductor element are encapsulated with a cured article of the epoxy resin composition for semiconductor encapsulation according to the present invention.

Examples of the metal wire that electrically connects the electrical junction disposed on the lead frame or circuit substrate and the electrode pad disposed on the semiconductor element include a gold wire, a copper wire, and an aluminum wire.

Among these, in the semiconductor device of the present invention wherein the epoxy resin composition for semiconductor encapsulation according to the present invention is used, even in the case of using a copper wire that is low cost, a highly reliable semiconductor device is attainable, because corrosion is not easily developed at the junction to the electrode pad disposed on the semiconductor element. In addition, improvements of the electrical performance of the semiconductor device such as reduction in electrical resistance are attainable.

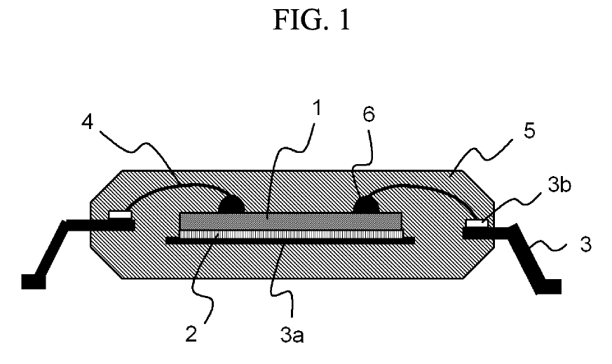

An example of the semiconductor device of the present invention is described with reference to FIG. 1. The semiconductor device of the present invention shown in FIG. 1 includes a lead frame 3 that has a die pad unit 3a; a semiconductor element 1 on which the die pad unit 3a is mounted; a metal wire 4 that electrically connects the lead frame 3 and the semiconductor element 1; and an encapsulation resin 5 that is a cured article of the aforementioned epoxy resin composition for semiconductor encapsulation and encapsulates the semiconductor element 1 and the metal wire 4.

The semiconductor element 1 is not particularly limited, but examples thereof include an integrated circuit, a large-scale integrated circuit, a solid-state image-sensing element, a semiconductor element using SiC, a power semiconductor such as power transistors, and an on-vehicle electronic component.

The lead frame 3 that is used in the present invention is not particularly limited. A circuit substrate may be used in place of the lead frame 3. Specifically, lead frames or circuit substrates that are used in conventional semiconductor devices are usable, including a dual inline package (DIP), a plastic leaded chip carrier (PLCC), a quad flat package (QFP), a low profile quad flat package (LQFP), a small outline j-lead package (SOJ), a thin small outline package (TSOP), a thick quad flat package (TQFP), a tape carrier package (TCP), a ball grid array (BGA), a chip size package (CSP), a quad flat non-leaded package (QFN), a small outline non-leaded package (SON), a lead frame BGA (LF-BGA), and a mold array package BGA (MAP-BGA).

The semiconductor element 1 may be a stack of two or more semiconductor elements. In this case, a semiconductor element of a first layer is bonded to the die pad 3a through a cured body 2 of a die-bonding material such as a film adhesive and a thermosetting adhesive. Semiconductor elements of second and further layers are successively stacked with an insulating film adhesive. The electrode pad 6 is provided on each appropriate layer such as a top layer.

The electrode pad 6 contains aluminum as a main ingredient. The purity of aluminum that is used for the electrode pad 6 is not particularly limited, but preferably 99.5% by mass or more. The electrode pad 6 may be provided as a conventional titanium barrier layer that is formed on the surface of copper circuit terminals of an underlayer; and then aluminum is applied by using conventional methods of forming electrode pads of semiconductor elements such as vacuum deposition, sputtering, and electroless plating.

The metal wire 4 is used to electrically connect the electrical junction that is disposed on the lead frame 3 and the electrode pad disposed on the semiconductor element 1 that is mounted on the die pad unit 3a of the lead frame 3. On the surface of the metal wire 4, an oxide film is formed spontaneously or unavoidably in processes depending on the kinds of metal wires. In the present invention, the metal wire 4 also includes the wire described above that has the oxide film on the surface thereof.

The diameter of the metal wire is preferably 30 μm or less, more preferably 25 μm or less, and preferably 15 μm or more. Within this range, the ball shape at the tip of the metal wire is stabilized, so that connection reliability is enhanced at the junction. In addition, the hardness of the metal wire itself reduces the frequency of wire flow.

When a copper wire is used as the metal wire, 99.9% by mass or more of copper purity is preferable, and 99.99% by mass or more is more preferable. Generally, the ball shape at the tip of the copper wire may be stabilized upon bonding by an addition of various kinds of elements (dopant) to copper. However, when the dopant is added in a large amount of more than 0.1% by mass, the ball becomes harder and damages the electrode pad 6 of the semiconductor element 1 upon wire-bonding. Inconveniences such as degradation in the humidity resistance reliability, degradation in high-temperature storage performance, and increase in electrical resistance sometimes arise. To the contrary, a copper wire that has a copper purity of 99.9% by mass or more provides a ball that has a sufficient softness, so that the ball does not damage the electrode pad upon bonding.

Note that the copper wire that is usable in the semiconductor device of the present invention is provided with still more improved ball shape and bonding strength by doping Ba, Ca, Sr, Be, Al, or rare-earth metals in an amount of from 0.001% by mass to 0.003% by mass in the copper core wire.

Further, when a copper wire is used as the metal wire, preferably, the copper wire has a coating layer of a palladium-containing metal material on the surface thereof. Whereby, the ball shape at the tip of the copper wire is stabilized and connection reliability at the junction is enhanced. In addition, an effect of preventing oxidation degradation of copper core wire is also obtained, so that the high-temperature storage performance of the junction is enhanced.

In the copper wire, the thickness of the coating layer that is composed of the palladium-containing metal material is preferably 0.001 μm to 0.02 μm, and more preferably 0.005 μm to 0.015 μm. Over the aforementioned upper limit, copper core wire and the palladium-containing metal material of the coating layer are not sufficiently fused upon wire-bonding and the ball shape becomes unstable, whereby the moisture resistance and the high-temperature storage performance of the junction may be degraded. Under the aforementioned lower limit, oxidation degradation of the copper core wire is not sufficiently prevented, whereby the moisture resistance and high-temperature storage performance of the junction may be degraded similarly.

The copper wire is obtained as a copper alloy cast in a melting furnace; the resulting ingot is extended by rolling and is further subjected to wire drawing with a die; the resulting wire is heated while the wire is continuously drawn and then, the wire is subjected to heat treatment. In the copper wire that is used in the semiconductor device of the present invention, the coating layer that is composed of the palladium-containing metal material is formed as a wire having an objective diameter; the wire is immersed and plated in an electrolytic or electroless solution that contains palladium while the wire is continuously drawn. Here, the thickness of the coating layer may be regulated by the drawing speed. Alternatively, another process may be used, where a wire that has a thicker diameter than the objective one is prepared; the wire is immersed in the electrolytic or electroless solution and drawn continuously so as to form the coating layer; and then, the wire is drawn until the objective diameter is attained.

The electrical junction (on the lead side) 3b of the lead frame 3 and the electrode pad 6 that is disposed on the semiconductor element 1 may be bonded together by wire reverse bonding. In the wire reverse bonding, at first, to the electrode pad 6 of the semiconductor element 1, a ball formed at the tip of the metal wire 4 is bonded; the metal wire 4 is cut off so as to form a bump for stitch-bonding; then, to the metal plated lead 3b of the lead frame 3, the ball that is formed at the tip of the wire is bonded so as to be stitch-bonded to the bump of the semiconductor element 1. In the reverse bonding, wire height over the semiconductor element 1 becomes lower as compared with forward bonding, so that junction height of the semiconductor element 1 is made to be low.

The semiconductor device of the present invention is obtained through encapsulation of an electronic component such as a semiconductor element with the epoxy resin composition for semiconductor encapsulation, and curing and molding by conventional molding processes such as transfer molding, compression molding, and injection molding. The semiconductor device that is encapsulated through the molding processes such as transfer molding is mounted on an electronic instrument as it is, or after it is fully cured at a temperature of about 80° C. to 200° C. for about 10 min to 10 h.

The encapsulation resin 5 is a cured article of the epoxy resin composition for semiconductor encapsulation according to the present invention.

In this way, in the semiconductor device of the present invention, a semiconductor element that is mounted on a lead frame having a die pad unit or a circuit substrate and a metal wire that electrically connects an electrical junction disposed on the lead frame or the circuit substrate and an electrode pad disposed on the semiconductor element are encapsulated with a cured article of the epoxy resin composition for semiconductor encapsulation according to the present invention. The epoxy resin (A) that is used in the epoxy resin composition for semiconductor encapsulation has a main peak area of 90% or more with respect to the total area of all peaks as measured by the gel permeation chromatography area method, so that, even in the case of using a copper wire that is low cost, corrosion at the junction to the electrode pad on the semiconductor element is reduced. Whereby, a highly reliable semiconductor device that has low frequency of electrical resistance elevation or wire-cutting at the junction is attainable.

When a copper wire is used as the metal wire, the copper wire is low cost, so that it is useful for cost-reduction of semiconductor devices. However, when the semiconductor element 1 that is connected to the copper wire is encapsulated with conventional epoxy resin compositions for semiconductor encapsulation, the humidity resistance reliability is sometimes lowered.

The corrosion mechanism at the junction between the copper wire and the aluminum electrode pad 6 of the semiconductor element 1 may be considered as follows. At the junction interface between the copper wire and the aluminum electrode pad 6 of the semiconductor element 1, an alloy of copper and aluminum is formed. The alloy of copper and aluminum forms a galvanic pair, so that the electrochemical activity thereof is high and the corrosion resistance thereof is low. Under high temperature and high humidity conditions, chloride ions are generated by hydrolysis of the cured article of the epoxy resin composition for semiconductor encapsulation that composes the encapsulation resin 5. The chloride ions corrode the alloy layer of copper and aluminum that is low in corrosion resistance. Whereby, an increase in electrical resistance or wire-cutting occurs at the junction.

Here, by using the epoxy resin (A) that has a small chlorine content, the amount of corrosive chloride ions, which are generated from the encapsulation resin 5 when the semiconductor device is treated at high temperature and high humidity, is reduced. In this way, corrosion at the junction between the copper wire and the aluminum electrode pad 6 of the semiconductor element 1 is prevented. Due to this, even in the case of using a copper wire as the metal wire, the semiconductor device of the present invention is provided with excellent humidity resistance reliability.

For example, when the semiconductor device of the present invention is subjected to HAST treatment (130° C., 85% RH, and 20 V), where the semiconductor device that increases the electrical resistance between wirings by 20% with respect to the initial value is evaluated to have a fault, desirably no fault occurs after the device is treated for 192 h.

Generally, semiconductor devices are required to have 96-h resistance in the HAST treatment (130° C., 85% RH, and 20 V). Considering this, sufficient reliability is assured when no fault occurs after 192 h in the HAST treatment (130° C., 85% RH, and 20 V).

As mentioned above, by using the epoxy resin composition for semiconductor encapsulation according to the present invention, which includes therein the epoxy resin (A), the curing agent (B), and the inorganic filler (C) and is characterized in that the epoxy resin (A) has a main peak area of 90% or more with respect to the total area of all peaks as measured by the gel permeation chromatography area method, the semiconductor device of the present invention that has a reduced frequency of wire-cutting fault and a high humidity resistance reliability.

Embodiments of the present invention are described above with reference to figures. These are examples of the present invention. Various configurations besides the above may be adoptable.

### EXAMPLES

Hereinafter, specific examples are described. The present invention is not limited to these specific examples. Each component of the epoxy resin compositions used in the examples and comparative examples is described below.

Epoxy Resin

Epoxy resin A: biphenyl epoxy resin (in the formula (1), each Rat the positions of 3, 3′, 5, and 5′ is a methyl group and each R at the positions of 2, 2′, 6, and 6′ is a hydrogen atom; “YX4000H” (trade name, manufactured by Mitsubishi Chemical Corp.); having an epoxy equivalence of 193, a total chlorine content of 400 ppm, a hydrolysable chlorine content of 150 ppm, and a ratio of main peak area to total area of all peaks of 83.7% as measured by the gel permeation chromatography area method).
Epoxy resin B: biphenyl epoxy resin (in the formula (1), each R at the positions of 3, 3′, 5, and 5′ is a methyl group and each R at the positions of 2, 2′, 6, and 6′ is a hydrogen atom; “YL7684” (trade name: manufactured by Mitsubishi Chemical Corp.); having an epoxy equivalence of 184, a total chlorine content of 158 ppm, a hydrolysable chlorine content of 80 ppm, and a ratio of main peak area/total area of all peaks of 92.4% as measured by the gel permeation chromatography area method).
Epoxy resin C: biphenyl epoxy resin (in the formula (1), each R at the positions of 3, 3′, 5, and 5′ is a methyl group and each R at the positions of 2, 2′, 6, and 6′ is a hydrogen atom; “YX 4000” (trade name: manufactured by Mitsubishi Chemical Corp.); having an epoxy equivalence of 177, a total chlorine content of 15 ppm, a hydrolysable chlorine content of less than 10 ppm, and a ratio of main peak area/total area of all peaks of 99.7% as measured by the gel permeation chromatography area method).

Curing Agent

Curing agent A: phenolaralkyl resin; “XLC-2L” (trade name), manufactured by Mitsui Chemicals, Inc.; having a hydroxyl group equivalence of 175; and a melt viscosity at 150° C. of 360 mPa·s.
Curing agent B: phenolnovolak resin; “PR-HF-3” (trade name), manufactured by Sumitomo Bakelite Co., Ltd.; having a softening point of 80° C. and a hydroxyl group equivalence of 104.

Filler

Fused spherical silica (having an average diameter of 26.5 μm; containing 1% by weight or less of particles that have a diameter of 105 μm or more; “FB-820” (trade name, manufactured by DENKI KAGAKU KOGYO KABUSHIKI KAISHA).

Curing Promoter

Curing promoter: 1,4-benzoquinone adduct of triphenyl phosphine (TPP; “PP360” (trade name, manufactured by K•I Chemical Industry Co., Ltd.).

Coupling Agent

Coupling agent: γ-glycidoxypropyl trimethoxysilane

Besides the aforementioned components, carbon black as a colorant and carnauba wax as a mold-releasing agent were used.

### Production of Epoxy Resin Composition:

### Example 1

The epoxy resin B (6.55 parts by mass), the curing agent A (6.20 parts by mass), the fused spherical silica as filler (86.00 parts by mass), the curing promoter (0.20 part by mass), the coupling agent (0.25 part by mass), carbon black as a colorant (0.30 part by mass), and carnauba wax as a mold-releasing agent (0.50 part by mass) were blended with a mixing machine at 15° C. to 28° C. and then kneaded with rolls at 70° C. to 100° C. After cooling and pulverization, an epoxy resin composition was obtained.

### Examples 2 to 4, Comparative Examples 1 and 2

In accordance with blending prescriptions for epoxy resin compositions for semiconductor encapsulation that are described in Table 1, epoxy resin compositions for semiconductor encapsulation were obtained in a manner similar to Example 1. All of the blending ratios described in Table 1 are in terms of part(s) by mass.

### Fabrication of Semiconductor Devices:

A TEG (TEST ELEMENT GROUP) chip (3.5 mm×3.5 mm) that had aluminum electrode pads was bonded to a die pad unit of a 352-pin BGA (substrate thickness is 0.56 mm; a bismaleimide triazine resin/glass cloth substrate; package size is 30×30 mm and thickness is 1.17 mm); and the aluminum electrode pads of the TEG chip and the electrode pads of the substrate were wire-bonded with a copper wire 4N (copper purity is 99.99% by mass) at a wire pitch of 80 μm in a daisy-chain connection. These were encapsulated with any of the epoxy resin compositions for semiconductor encapsulation of Examples 1 to 4 and Comparative Examples 1 and 2, and molded with a low-pressure transfer molding machine (“Y Series” (trade name, manufactured by TOWA Corp.)) under conditions of 175° C. of mold temperature, 6.9 MPa of injection pressure, and 2 min of curing time. Whereby, 352-pin BGA packages were fabricated. The packages were post-cured under conditions of 175° C. and 4 h so as to obtain semiconductor devices.

### Evaluation Method:

(1) Evaluation of Properties of Epoxy Resin Compositions

The properties of the resulting epoxy resin compositions were evaluated by the following method. The results are shown in Table 1.

Spiral Flow (SF)

Using a low-pressure transfer molding machine (“KTS-15” (trade name, manufactured by Kohtaki Precision Machine Co., Ltd.)), each of the epoxy resin compositions for semiconductor encapsulation of Examples 1 to 4 and Comparative Examples 1 and 2 was injected into a mold for the spiral flow measurement in accordance with EMMI-1-66 so as to measure a flow length (unit: cm) under conditions of 175° C. of mold temperature, 6.9 MPa of injection pressure, and 120 s of curing time. When the length was 60 cm or less, molding fault such as non-filling package sometimes occurred.

Gel Time (GT)

Each of the epoxy resin compositions for semiconductor encapsulation of Examples 1 to 4 and Comparative Examples 1 and 2 was fused on a 175° C. heat plate, and the time that was required until the epoxy resin composition was cured was measured while the epoxy resin composition was kneaded with a spatula.

The results are shown in Table 1.

(2) Evaluation of Performance of Semiconductor Devices

The humidity resistance reliability (HAST) of the fabricated 352-pin BGA semiconductor devices was measured by the following method. The results are shown in Table 1.

HAST

While a 352-pin BGA package was used, in accordance with IEC 68-2-66, the HAST (Highly Accelerated temperature and humidity Stress Test) was performed. The test conditions were 130° C., 85% RH, and 20 V of applied voltage. Circuit open fault was evaluated after 96 h, 192 h, or 1008 h of treatment time. Four terminals for every package were selected, and five packages, that is, twenty circuits were evaluated. The unit is the number of fault circuits.

Evaluation Criteria

In the HAST, the case of no fault after 1008-h treatment was evaluated to be AA; the case of no fault after 192-h treatment was evaluated to be A; and the other cases were evaluated to be C.

TABLE 1

| | | Examples | | | | Comparative Examples | |
|---|---|---|---|---|---|---|---|
| No. | | 1 | 2 | 3 | 4 | 1 | 2 |
| Fused spherical silica | | 86.00 | 88.00 | 86.00 | 88.00 | 86.00 | 88.00 |
| Carbon black | | 0.30 | 0.30 | 0.30 | 0.30 | 0.30 | 0.30 |
| Coupling agent | | 0.25 | 0.25 | 0.25 | 0.25 | 0.25 | 0.25 |
| Epoxy resin A | | | | | | 6.70 | 6.96 |
| Epoxy resin B | | 6.55 | 6.84 | | | | |
| Epoxy resin C | | | | 6.43 | 6.75 | | |
| Curing agent A | | 6.20 | | 6.32 | | 6.05 | |
| Curing agent B | | | 3.91 | | 4.00 | | 3.79 |
| Curing promoter | | 0.20 | 0.20 | 0.20 | 0.20 | 0.20 | 0.20 |
| Carnauba wax | | 0.50 | 0.50 | 0.50 | 0.50 | 0.50 | 0.50 |
| Total | | 100.00 | 100.00 | 100.00 | 100.00 | 100.00 | 100.00 |
| SF | Cm | 80 | 72 | 82 | 73 | 76 | 77 |
| GT | Sec | 37 | 39 | 38 | 40 | 37 | 38 |
| HAST | 96 h | 0 | 0 | 0 | 0 | 0 | 0 |
| | 192 h | 0 | 0 | 0 | 0 | 2 | 3 |
| | 1008 h | 2 | 4 | 0 | 0 | 20 | 20 |
| Evaluation | | A | A | AA | AA | C | C |

As shown in Table 1, semiconductor devices with encapsulation resins that are provided by curing the epoxy resin compositions for semiconductor encapsulation of Examples 1 to 4 exhibit no fault in the HAST evaluation of 192-h treatment.

### FIELD OF INDUSTRIAL APPLICATION

In the case of using a semiconductor element that is mounted on a lead frame having a die pad unit or a circuit substrate and a metal wire, especially, a copper wire that electrically connects an electrical junction disposed on the lead frame or circuit substrate and an electrode pad disposed on the semiconductor element, the epoxy resin composition for semiconductor encapsulation according to the present invention suppresses corrosion at the junction between the electrode pad on the semiconductor element and the copper wire under high-temperature and high-humidity conditions. The epoxy resin composition is suitably used for the manufacture of semiconductor devices with low cost and improved reliability.

### BRIEF DESCRIPTION OF THE REFERENCE SYMBOLS

1 Semiconductor element
2 Cured article of die-bonding material
3 Lead frame
3a Die pad unit
3b Electrical junction of lead frame (lead)
4 Metal wire (copper wire)
5 Encapsulation resin
6 Electrode pad

1. An epoxy resin composition for semiconductor encapsulation, which is used to produce a semiconductor device by encapsulating a semiconductor element that is mounted on a lead frame having a die pad unit or a circuit substrate, and a metal wire that electrically connects an electrode pad disposed on the semiconductor element and an electrical junction disposed on the lead frame or the circuit substrate; the epoxy resin composition for semiconductor encapsulation comprises an epoxy resin (A), a curing agent (B), and an inorganic filler (C), wherein the epoxy resin (A) has a main peak area of 90% or more with respect to the total area of all peaks as measured by a gel permeation chromatography area method.

2. The epoxy resin composition for semiconductor encapsulation according to claim 1, wherein the epoxy resin (A) has a main peak area of 92% or more with respect to the total area of all peaks as measured by the gel permeation chromatography area method.

3. The epoxy resin composition for semiconductor encapsulation according to claim 1, wherein the epoxy resin (A) has a total chlorine content of 300 ppm or less and a hydrolysable chlorine content of 150 ppm or less.

4. The epoxy resin composition for semiconductor encapsulation according to claim 1, wherein the epoxy resin (A) has a total chlorine content of 200 ppm or less and a hydrolysable chlorine content of 100 ppm or less.

5. The epoxy resin composition for semiconductor encapsulation according to claim 1, wherein the epoxy resin (A) comprises an epoxy resin which is represented by the following formula (1): 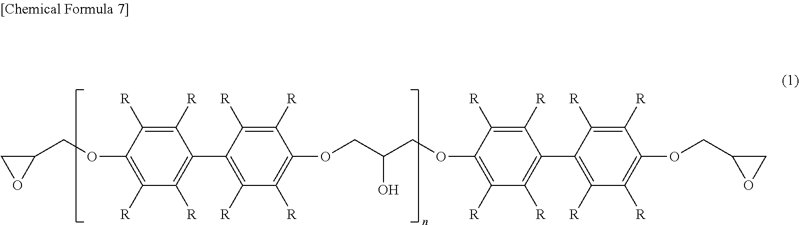
in which each R represents, independently from one another, a hydrogen atom or a hydrocarbon group having 1 to 4 carbon atoms; n represents polymerization degree; and the average value of n is a positive number from 0 to 4.

6. The epoxy resin composition for semiconductor encapsulation according to claim 1, wherein a blending ratio of the epoxy resin (A) is from 3% by mass to 20% by mass with respect to the total amount of the epoxy resin composition for semiconductor encapsulation.

7. The epoxy resin composition for semiconductor encapsulation according to claim 1, wherein the metal wire is a copper wire.

8. The epoxy resin composition for semiconductor encapsulation according to claim 7, wherein a dopant in an amount of 0.1% by mass or less with respect to copper of the copper wire is added, and the copper purity of the copper wire is 99.9% by mass or more.

9. A semiconductor device, comprising a semiconductor element mounted on a lead frame having a die pad unit or on a circuit substrate, and a metal wire electrically connecting an electrical junction disposed on the lead frame or the circuit substrate and an electrode pad disposed on the semiconductor element, and the semiconductor element and the metal wire being encapsulated with a cured article of the epoxy resin composition for semiconductor encapsulation according to claim 1.

10. The semiconductor device according to claim 9, wherein the metal wire is a copper wire.

11. The epoxy resin composition for semiconductor encapsulation according to claim 2, wherein the epoxy resin (A) has a total chlorine content of 300 ppm or less and a hydrolysable chlorine content of 150 ppm or less.

12. The epoxy resin composition for semiconductor encapsulation according to claim 2, wherein the epoxy resin (A) has a total chlorine content of 200 ppm or less and a hydrolysable chlorine content of 100 ppm or less.

13. The epoxy resin composition for semiconductor encapsulation according to claim 2, wherein the epoxy resin (A) comprises an epoxy resin which is represented by the following formula (1): 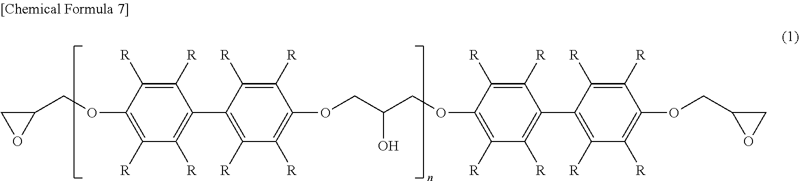
in which each R represents, independently from one another, a hydrogen atom or a hydrocarbon group having 1 to 4 carbon atoms; n represents polymerization degree; and the average value of n is a positive number from 0 to 4.

14. The epoxy resin composition for semiconductor encapsulation according to claim 3, wherein the epoxy resin (A) comprises an epoxy resin which is represented by the following formula (1): 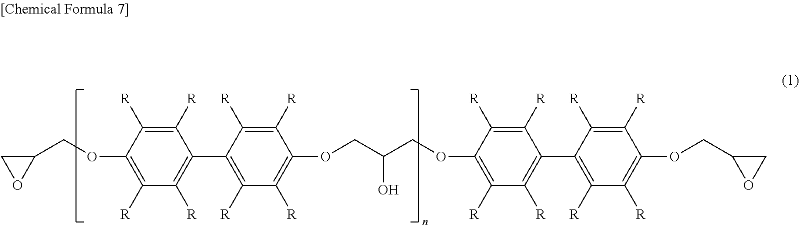
in which each R represents, independently from one another, a hydrogen atom or a hydrocarbon group having 1 to 4 carbon atoms; n represents polymerization degree; and the average value of n is a positive number from 0 to 4.

15. The epoxy resin composition for semiconductor encapsulation according to claim 4, wherein the epoxy resin (A) comprises an epoxy resin which is represented by the following formula (1): 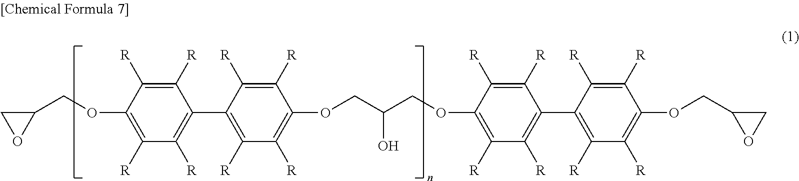
in which each R represents, independently from one another, a hydrogen atom or a hydrocarbon group having 1 to 4 carbon atoms; n represents polymerization degree; and the average value of n is a positive number from 0 to 4.

16. The epoxy resin composition for semiconductor encapsulation according to claim 2, wherein a blending ratio of the epoxy resin (A) is from 3% by mass to 20% by mass with respect to the total amount of the epoxy resin composition for semiconductor encapsulation.

17. The epoxy resin composition for semiconductor encapsulation according to claim 3, wherein a blending ratio of the epoxy resin (A) is from 3% by mass to 20% by mass with respect to the total amount of the epoxy resin composition for semiconductor encapsulation.

18. The epoxy resin composition for semiconductor encapsulation according to claim 4, wherein a blending ratio of the epoxy resin (A) is from 3% by mass to 20% by mass with respect to the total amount of the epoxy resin composition for semiconductor encapsulation.

19. The epoxy resin composition for semiconductor encapsulation according to claim 5, wherein a blending ratio of the epoxy resin (A) is from 3% by mass to 20% by mass with respect to the total amount of the epoxy resin composition for semiconductor encapsulation.

20. The epoxy resin composition for semiconductor encapsulation according to claim 2, wherein the metal wire is a copper wire.
